(19) United States
(12) Patent Application Publication
(10) Pub. No.: US 2011/0303283 A1
(43) Pub. Date: Dec. 15, 2011

(54) SOLAR CELL STRUCTURE OF GROUP III-V SEMICONDUCTOR AND METHOD OF MANUFACTURING THE SAME

(75) Inventors: YEE SHYI CHANG, TAIPEI (TW); CHI-JEN LIU, TAIPEI (TW)

(73) Assignee: AN CHING NEW ENERGY MACHINERY & EQUIPMENT CO., LTD ., Taipei (TW)

(21) Appl. No.: 13/017,547

(22) Filed: Jan. 31, 2011

(30) Foreign Application Priority Data
Jun. 11, 2010 (TW) 99119056

(51) Int. Cl. H01L 31/0256; H01L 31/18

(52) U.S. Cl. 136/258; 438/97; 257/E31.043

(57) ABSTRACT

A solar cell structure of Group III-V semiconductor and method of manufacturing the same, comprising: a transparent substrate, an amorphous silicon layer, and at least a Group III-V polycrystalline semiconductor layer. Wherein, said amorphous silicon layer is formed on said transparent substrate through Plasma Enhanced Chemical Vapor Deposition (PECVD), and said Group III-V polycrystalline semiconductor layer is formed on said amorphous silicon layer sequentially by means of Metal-Organic Chemical Vapor Deposition (MOCVD). In said solar cell structure mentioned above, said transparent substrate replaces a conventional Group III-V substrate, hereby reducing its cost significantly, increasing surface area of said solar cell structure, hence increasing its light absorption area, and raising its photoelectric conversion efficiency.

### BACKGROUND OF THE INVENTION

1. Field of the Invention

The present invention relates to a solar cell structure, and in particular to a solar cell structure of Group III-V semiconductor and method of manufacturing the same.

2. The Prior Arts

Due to the limited energy resources on earth, and the insatiable needs for energy, thus the solar energy industry has emerged as the most promising energy resource for the future. The solar energy is a kind of green, environment friendly and perpetual energy resource, as such the solar cell is able to convert and store energy of sunlight in a form of electricity for various applications. Usually, a solar cell is capable of absorbing photons and solar energy by means of semiconductor, so as to agitate the electrons to drive the circuit for generating electricity. Presently, various types of solar cells utilized are made of mono-crystalline silicon, polycrystalline silicon, amorphous silicon semiconductors or Group III-V, Group II-VI materials.

The Group III-V solar cell, also referred to as a concentrator type solar cell, is capable of having photoelectric conversion efficiency much higher than that of silicon crystal solar cell, meanwhile, it has the flexibility of a thin film solar cell. The Group III-V solar cell is made by depositing GaAs thin film on Group III-V substrate by means of Chemical Vapor Deposition (CVD). The solar cell thus produced has already been used enormously on the solar cell panel of satellites for quite some time, and it has the advantage of being capable of absorbing lights of a fairly wide range of spectrum, stable in operation, photoelectric conversion efficiency in excess of 30%, and a service life longer than that of any other types of solar cells. Though the Group III-V solar cell does not need to use silicon crystal, yet the cost of chips utilized is still rather high, and this problem has to be overcome urgently in the solar energy industry.

Therefore, presently, the design and application of a solar cell of the prior art are not quite satisfactory, and it has much room for improvement.

### SUMMARY OF THE INVENTION

In view of the problems and shortcomings of the prior art, the present invention provides a solar cell structure of Group III-V semiconductor, that can solve the problem of the prior art.

A major objective of the present invention is to provide a solar cell structure of Group III-V semiconductor and method of manufacturing the same, such that a transparent substrate is used to replace the Group III-V substrate of the prior art, hereby reducing its cost significantly.

Another objective of the present invention is to provide a solar cell structure of Group III-V semiconductor and method of manufacturing the same, wherein, transparent substrate of low cost is utilized, so as to increase the surface area of the solar cell, and hence increase its light absorption area and its photoelectric conversion efficiency.

In order to achieve the above-mentioned objective, the present invention provide a solar cell structure of Group III-V semiconductor, comprising: a transparent substrate; an amorphous silicon layer, deposited on the transparent substrate through using Plasma Enhanced Chemical Vapor Deposition (PECVD); and at least a Group III-V polycrystalline semiconductor layer deposited on the amorphous silicon layer by means of Metal-Organic Chemical Vapor Deposition (MOCVD).

In addition, the present invention provides a method of manufacturing a solar cell structure, comprising the following steps: forming an amorphous silicon layer on a transparent substrate; and depositing in sequence at least a Group III-V polycrystalline semiconductor layer on the amorphous silicon layer.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a cross section view of a solar cell structure of Group III-V semiconductor according to an embodiment of the present invention;

FIG. 2 is a is a cross section view of a solar cell structure of Group III-V semiconductor according to another embodiment of the present invention; and

FIG. 3 is a flowchart of the steps of a method of manufacturing a solar cell structure of Group III-V semiconductor according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

The present invention provides a solar cell structure of Group III-V semiconductor and a method of manufacturing the same, such that this kind of solar cell can be put on a wall and a roof of a building, so as to be irradiated by sunlight and absorb solar energy, for converting it into electrical energy of daily usage.

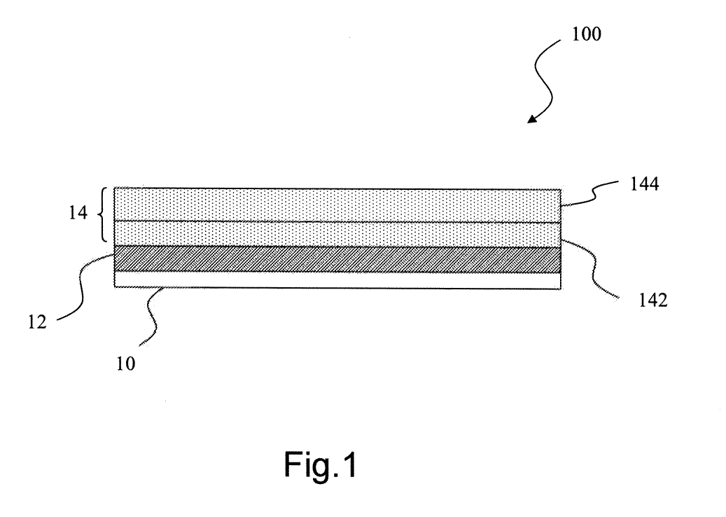

Refer to FIG. 1 for a cross section view of a solar cell structure 100 of Group III-V semiconductor according to an embodiment of the present invention, comprising a transparent substrate 10, an amorphous silicon layer 12, and at least a Group III-V polycrystalline semiconductor layer 14. Wherein, the transparent substrate 10 is made of glass, quartz, transparent plastic, or mono-crystalline Aluminum Oxide; the amorphous silicon layer 12 is formed on the transparent substrate 10; and the Group III-V polycrystalline semiconductor layer 14 made of InN, InGaN, AlAs, AlGaAs, or GaAs, and the Group III-V polycrystalline semiconductor layer 14 is formed on the amorphous silicon layer 12.

In case that the Group III-V polycrystalline semiconductor layer 14 includes two layers, as shown in FIG. 1, namely, a first type semiconductor layer 142 and a second type semiconductor layer 144, such that, when the first type semiconductor layer 142 is a P type polycrystalline semiconductor, then the second type semiconductor layer 144 is an N+ type polycrystalline semiconductor; or when the first type semiconductor layer 142 is an N+ type polycrystalline semiconductor, then the second type semiconductor layer 144 is a P type polycrystalline semiconductor. By way of example, the case of InGaN is taken as an example, when the first type semiconductor layer 142 is a P type polycrystalline InGaN semiconductor layer, then the second type semiconductor layer 144 is an N+ type polycrystalline InGaN semiconductor layer.

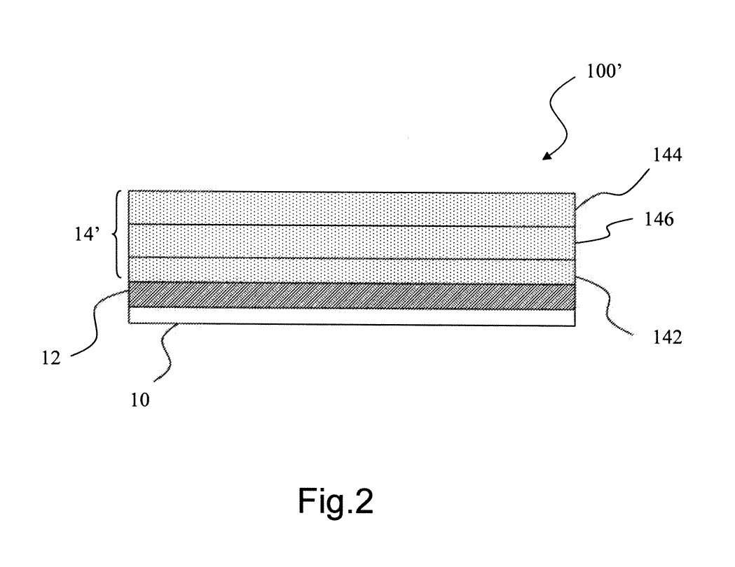

Next, refer to FIG. 2 for a is a cross section view of a solar cell structure 100′ of Group III-V semiconductor according to another embodiment of the present invention. In this embodiment, the Group III-V polycrystalline semiconductor layer 14′ includes three layer, namely, a first type semiconductor layer 142, a second type semiconductor layer 144, and an intrinsic semiconductor layer 146, such that, when the first type semiconductor layer 142 is a P type polycrystalline semiconductor, then the second type semiconductor layer 144 is an N+ type polycrystalline semiconductor, and the intrinsic semiconductor layer 146 is an I type polycrystalline semiconductor ; or when the first type semiconductor layer 142 is an N+ type polycrystalline semiconductor, then the second type semiconductor layer 144 is a P type polycrystalline semiconductor, and the intrinsic semiconductor layer 146 is an I type polycrystalline semiconductor. By way of example, the case of InGaN is taken as an example, when the first type semiconductor layer 142 is a P type polycrystalline InGaN semiconductor layer, then the second type semiconductor layer 144 is an N+ type polycrystalline InGaN semiconductor layer, and the intrinsic semiconductor layer 146 is an I type polycrystalline InGaN semiconductor layer.

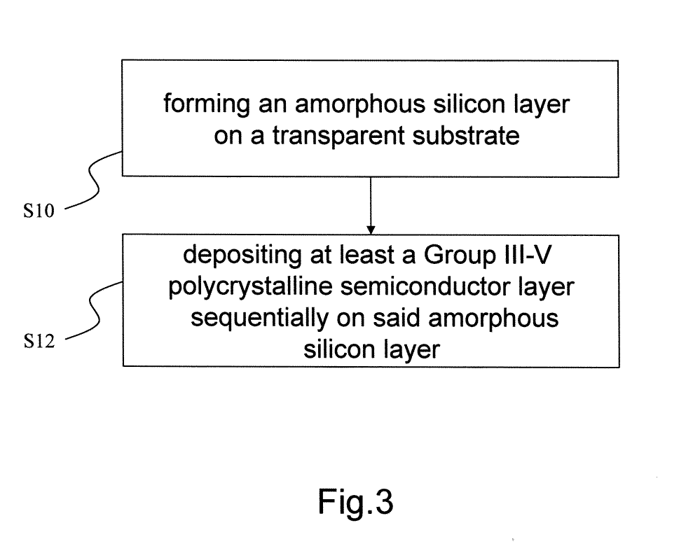

Finally, refer to FIG. 3 for a flowchart of the steps of a method of manufacturing a solar cell structure of Group III-V semiconductor according to the present invention. As shown in FIG. 3, in step Sb, forming an amorphous silicon layer on a transparent substrate through using Plasma Enhanced Chemical Vapor Deposition (PECVD); and in step S12, depositing at least a Group III-V polycrystalline semiconductor layer in sequence on the amorphous silicon layer by means of Metal-Organic Chemical Vapor Deposition (MOCVD). Though Group III-V semiconductor can not form on a transparent substrate, however, since the bonding and lattice of Group III-V semiconductor are similar to those of amorphous silicon, therefore, Group III-V semiconductor layer of the solar cell structure can be formed on a transparent substrate through utilizing an amorphous silicon layer. Subsequently, in step S12, the depositing of Group III-V polycrystalline semiconductor layer is realized through forming in sequence a first type semiconductor layer, and a second type semiconductor layer on said amorphous silicon layer; or forming in sequence a first type semiconductor layer, an intrinsic semiconductor layer, and a second type semiconductor layer on said amorphous silicon layer.

Summing up the above, the present invention provides a solar cell structure of Group III-V semiconductor and a method of manufacturing the same, wherein, the traditional Group III-V substrate is replaced by a transparent substrate, and through utilizing the lattice characteristics of the amorphous silicon layer, Group III-V polycrystalline semiconductor layer can be deposited on an amorphous silicon layer in achieving the solar cell structure, without having to use the costly Group III-V substrate, hereby reducing the cost significantly. Furthermore, since the cost of the transparent substrate utilized is low, therefore it is possible to produce solar cell of large surface area, thus further increasing its light absorption area and raising its photoelectric conversion efficiency.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A solar cell structure of Group III-V semiconductor, comprising:
a transparent substrate;
an amorphous silicon layer, formed on said transparent substrate; and
at least a Group III-V polycrystalline semiconductor layer, formed on said amorphous silicon layer.

2. The solar cell structure of Group III-V semiconductor as claimed in claim 1, wherein said transparent substrate is made of glass, quartz, transparent plastic, or mono-crystalline Al₂O₃.

3. The solar cell structure of Group III-V semiconductor as claimed in claim 1, wherein said amorphous silicon layer is formed on said transparent substrate by means of Plasma Enhanced Chemical Vapor Deposition (PECVD).

4. The solar cell structure of Group III-V semiconductor as claimed in claim 1, wherein said Group III-V polycrystalline semiconductor layer is formed on said amorphous silicon layer by means of Metal-Organic Chemical Vapor Deposition (MOCVD).

5. The solar cell structure of Group III-V semiconductor as claimed in claim 1, wherein said Group III-V polycrystalline semiconductor layer is made of InN, InGaN, AlAs, AlGaAs, or GaAs.

6. The solar cell structure of Group III-V semiconductor as claimed in claim 1, wherein in case that said Group III-V polycrystalline semiconductor layer is made of two layers, it includes a first type semiconductor layer and a second type semiconductor layer.

7. The solar cell structure of Group III-V semiconductor as claimed in claim 1, wherein in case that said Group III-V polycrystalline semiconductor layer is made of three layers, it includes said first type semiconductor layer, an intrinsic semiconductor layer, and said second type semiconductor layer.

8. The solar cell structure of Group III-V semiconductor as claimed in claim 6 or 7, wherein when said first type semiconductor layer is a P type polycrystalline semiconductor, then said second type semiconductor layer is an N+ type polycrystalline semiconductor; or when said first type semiconductor layer is said N+ type polycrystalline semiconductor, then said second type semiconductor layer is said P type polycrystalline semiconductor.

9. A solar cell structure manufacturing method, comprising the following steps:
forming an amorphous silicon layer on a transparent substrate; and
depositing at least a Group III-V polycrystalline semiconductor layer sequentially on said amorphous silicon layer.

10. The solar cell structure manufacturing method as claimed in claim 9, wherein said transparent substrate is made of glass, quartz, transparent plastic, or mono-crystalline Al₂O₃.

11. The solar cell structure manufacturing method as claimed in claim 9, wherein said amorphous silicon layer is formed on said transparent substrate by means of Plasma Enhanced Chemical Vapor Deposition (PECVD).

12. The solar cell structure manufacturing method as claimed in claim 9, wherein said Group III-V polycrystalline semiconductor layer is formed on said amorphous silicon layer by means of Metal-Organic Chemical Vapor Deposition (MOCVD).

13. The solar cell structure manufacturing method as claimed in claim 9, wherein said Group III-V polycrystalline semiconductor layer is made of InN, InGaN, AlAs, AlGaAs, or GaAs.

14. The solar cell structure manufacturing method as claimed in claim 9, wherein in case that said Group III-V polycrystalline semiconductor layer is made of two layers, it includes a first type semiconductor layer and a second type semiconductor layer.

15. The solar cell structure manufacturing method as claimed in claim 9, wherein in case that said Group III-V polycrystalline semiconductor layer is made of three layers, it includes said first type semiconductor layer, said intrinsic semiconductor layer, and said second type semiconductor layer.

16. The solar cell structure manufacturing method as claimed in claim 14 or 15, wherein when said first type semiconductor layer is said P type polycrystalline semiconductor layer, then said second type semiconductor layer is said N+ type polycrystalline semiconductor; or when said first type semiconductor layer is said N+ type polycrystalline semiconductor, then said second type semiconductor layer is said P type polycrystalline semiconductor.
